(19) United States
(12) Patent Application Publication
(10) Pub. No.: US 2018/0180808 A1
(43) Pub. Date: Jun. 28, 2018

(54) WAFER-LEVEL PACKAGED OPTOELECTRONIC MODULE

(71) Applicant: Oracle International Corporation, Redwood Shores, CA (US)

(72) Inventors: Chaoqi Zhang, Atlanta, GA (US); Hiren D. Thacker, San Diego, CA (US); Ashok V. Krishnamoorthy, San Diego, CA (US)

(73) Assignee: Oracle International Corporation, Redwood Shores, CA (US)

(21) Appl. No.: 15/388,186

(22) Filed: Dec. 22, 2016

(51) Int. Cl. G02B 6/12; G02B 6/42; H05K 1/18; H05K 1/11; H05K 3/30

(52) U.S. Cl. CPC G02B 6/12004; G02B 6/428; G02B 6/4255; H05K 3/306; G02B 6/12002; H05K 1/182; H05K 1/115; G02B 6/424

(57) ABSTRACT

The disclosed embodiments relate to an optoelectronic module, comprising one or more optical chips, and a molded substrate, which is molded around the one or more optical chips, so that the one or more optical chips are embedded in the molded substrate, and an active surface of each optical chip remains exposed. This molded substrate includes one or more through vias that provide electrical signal paths through the molded substrate. After the molded substrate is fabricated, one or more integrated circuit (IC) chips can be flip-mounted to the molded substrate and electrically connected to the one or more embedded optical chips and the one or more through vias. Also, one or more optical connectors containing optical waveguides can be flip-mounted on the molded substrate and optically coupled to the one or more embedded optical chips.

### GOVERNMENT LICENSE RIGHTS

This invention was made with U.S. government support under Agreement No. HR0011-08-9-0001 awarded by DARPA. The U.S. government has certain rights in the invention.

### FIELD

The disclosed embodiments generally relate to the design of optoelectronic circuits. More specifically, the disclosed embodiments relate to the design of a wafer-level packaged optoelectronic module, which is substrateless and is hence more compact than existing optoelectronic modules.

### RELATED ART

Silicon photonics is a promising new technology that can potentially provide large communication bandwidth, low latency and low power consumption for inter-chip and intra-chip connections. In order to achieve such connectivity, a number of optical components are required, including: lasers, optical modulators, optical detectors and optical switches. At the same time, practical techniques need to be developed to incorporate these optical components into computing systems. This has led researchers to develop techniques for fabricating optoelectronic modules, which integrate such optical components with semiconductor-based electrical components. For example, see U.S. patent application Ser. No. 14/605,650, entitled “Packaged Opto-Electronic Module,” by inventors Hiren D. Thacker, et al., filed 26 Jan. 2015. This patent application describes a packaged optoelectronic module (POeM), wherein the optical and electrical components are “hybrid integrated” using flip-chip manufacturing techniques to provide high-bandwidth system-level connectivity.

Hybrid integration is a practical approach for combining complementary metal-oxide-semiconductor (CMOS) integrated-circuit (IC) chips, the prevalent electronic circuit technology, with photonic components. By using a hybrid integration technique, each component may be built on its individually optimized technology platform. For example, see FIG. 1A, which illustrates an existing POeM 100 comprising a laser chip 106, an optical connector 108 and an integrated circuit (IC) chip 104, which are each sequentially flip-chip bonded onto an optical chip 110 that contains an optical waveguide 112. This bonding process creates a dual-diving board structure, wherein the footprint of the top dies (IC chip 104 and optical connector 108) extend beyond the footprint of the bottom die (optical chip 110). This multi-chip structure is then incorporated into a package substrate 102, which includes a cavity to accommodate optical chip 110. The choice of this integration technique is motivated in part to limit the use of high-precision flip-chip bonding equipment and high-temperature processes to the chip-to-chip integration, whereas industry-standard pick-and-place equipment and reflow processes may be used for component-to-substrate assembly. While fabricating a cavity in the package substrate is challenging and is not compatible with all materials, it eases assembly and allows low-parasitic chip-to-chip connections.

Another option for integrating photonic components with semiconductor chips is to use a die-embedding and build-up technology to construct an embedded multi-die Interconnect bridge (EMIB). (See R. Mahajan, et al., “Embedded Multi-Die Interconnect Bridge (EMIB)—A High Density, High Bandwidth Packaging Interconnect,” in Proceedings of 66^{th} ECTC, 2016.) However, in a EMIB platform, the bridge die thickness must be thin enough (˜50 um) to be embedded. This can potentially create handling and reliability problems during assembly. In addition, the organic package substrate used for power delivery and routing may also limit the module profile and energy-per-bit of the link.

Hence, what is needed is a practical technique for incorporating optical components with semiconductor-based electrical components without the drawbacks of the above-described techniques.

### SUMMARY

The disclosed embodiments relate to an optoelectronic module, comprising one or more optical chips, and a molded substrate, which is molded around the one or more optical chips, so that the one or more optical chips are embedded in the molded substrate, and an active surface of each optical chip remains exposed. This molded substrate includes one or more through vias that provide electrical signal paths through the molded substrate. After the molded substrate is fabricated, one or more IC chips can be flip-mounted to the molded substrate and electrically connected to the one or more embedded optical chips and the one or more through vias. Then, one or more optical connectors containing optical waveguides can be flip-mounted on the molded substrate and optically coupled to the one or more embedded optical chips.

In some embodiments, the one or more lasers are mounted to the molded substrate and optically coupled to the one or more embedded optical chips.

In some embodiments, the one or more through vias comprise through-mold vias (TMVs), which are formed in the molded substrate.

In some embodiments, the one or more through vias comprise through-silicon vias (TSVs) located in one or more interposer chips, which are embedded in the molded substrate.

In some embodiments, a face of the molded substrate, which is opposite from the exposed active surfaces of the embedded optical chips, includes a redistribution layer that facilitates routing signals from the one or more through vias to one or more electrical connectors, such as solder balls.

In some embodiments, the one or more optical connectors include at least one vertical optical connector.

In some embodiments, an over-molding layer is molded over the one or more IC chips and the molded substrate.

In some embodiments, the one or more IC chips and the one or more optical connectors are mounted to the molded substrate using an automated pick-and-place assembly process with wafer-level bonding.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1A illustrates an existing packaged optoelectronic module (POeM) in accordance with the disclosed embodiments.

FIG. 1B illustrates a wafer-level (WL)-POeM in accordance with the disclosed embodiments.

FIG. 2 illustrates a process flow for POeM integration using wafer-level packaging technology in accordance with the disclosed embodiments.

FIG. 3A illustrates an assembly process for a POeM in accordance with the disclosed embodiments.

FIG. 3B illustrates an assembly process for a WL-POeM in accordance with the disclosed embodiments.

FIG. 4 illustrates a WL-POeM with a vertical optical coupler in accordance with the disclosed embodiments.

FIG. 5 illustrates a process flow for a WL-POeM with an embedded interposer containing through silicon vias (TSVs) in accordance with the disclosed embodiments.

FIG. 6 illustrates a process flow for a WL-POeM with an additional over-molding process in accordance with the disclosed embodiments.

FIG. 7A illustrates a WL-POeM with dual optical chips in accordance with the disclosed embodiments.

FIG. 7B illustrates WL-POeMs with four optical chips in accordance with the disclosed embodiments.

FIG. 8 presents a flow chart of a process of fabricating a WL-POeM in accordance with the disclosed embodiments.

FIG. 9 illustrates a system that incorporates optical components with semiconductor chips in accordance with an embodiment of the present disclosure.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

### Implementation Details

In this disclosure we describe a packaged optoelectronic module (POeM) that leverages wafer-level packaging techniques to realize a more-compact optoelectronic component, which is substrateless, and consequently has a low package form factor. This WL-POeM is more manufacturing-compatible than a conventional POeM, because it has no diving boards, and is also higher yielding, which leads to lower costs. By eliminating the substrate entirely, this compact WL-POeM will have lower parasitic capacitances, and will therefore provide a higher energy per bit for photonic communications.

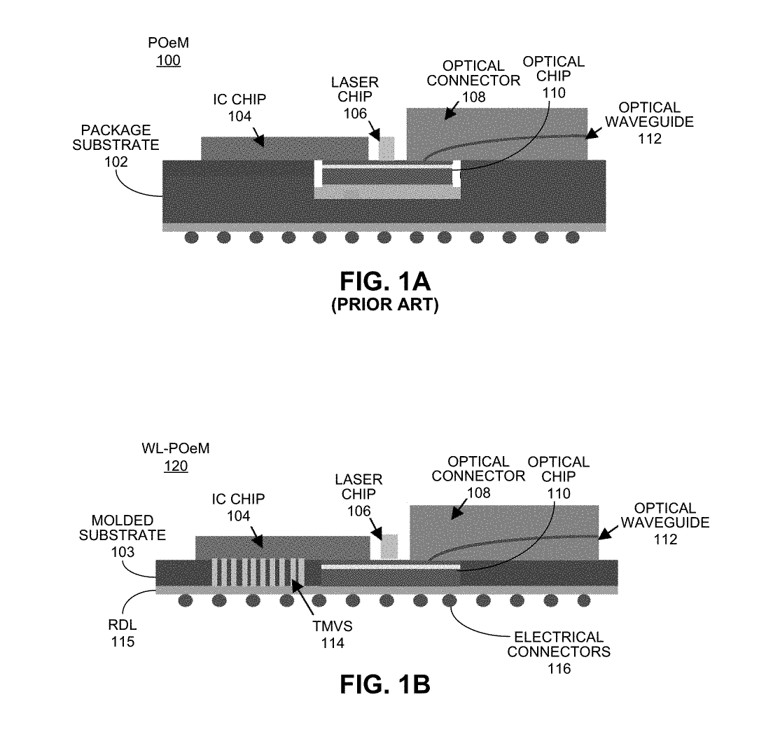

An exemplary WL-POeM 120 is illustrated in FIG. 1B. It comprises at least one IC chip 104, at least one optical chip 110 (which is embedded in a molded substrate 103), at least one laser chip 106, and at least one optical connector 108, which includes an optical waveguide 112 for signal transport. Note that IC chip 104 is oriented circuit-side down, so that it can electrically connect with the face-up optical chip 110 and the molded substrate 103. Also note that IC chip 104 can contain a number of different circuits, including but not limited to, modulator drivers, receivers, and control circuits, as well as serializer-deserializer (SERDES) circuits. Moreover, WL-POeM 120 may be manufactured in bulk CMOS, silicon-on-insulator (SOI), SiGe or using technologies.

Note that optical chip 110 can be electrically connected to other system components in a number of different ways. For example, optical chip 110 can electrically connect to other system components: through a redistribution layer (RDL) 115 (which can include one or more metal redistribution layers); through an IC chip 104; or through direct wire bonds (not shown). Moreover, optical chip 110 can contain a number of types of optical components, including modulators, multiplexers, demultiplexers, photodetectors, waveguides and fiber couplers. Note that an exemplary embodiment can be manufactured on a thin SOI technology platform (0.25 um), or alternatively a thick SOI technology platform (3 um). Optical chip 110 may also include monolithically integrated electronic circuits.

Molded substrate 103 is formed during a wafer-level packaging process, which is described in more detail below. Moreover, molded substrate 103 includes a number of through-molded vias (TMVs), which provide electrical pathways between IC chip 104 and RDL 115. As illustrated in FIG. 1B, molded substrate 103 has hybrid-integrated chips on one side, including IC chip 104, laser chip 106 and optical connector 108, and has electrical connectors 116 on the other side. These electrical connectors 116 may include an array of solder balls, pads, bumps, or pillars (e.g., copper pillars), and are designed to interface with a next-level package in a multichip module. Note that besides molded substrate 103, there is no additional package substrate or interposer in WL-POeM 120.

In order to route optical signals, an optical connector 108 is flip-chip bonded onto optical chip 110, wherein optical connector 108 includes an optical waveguide 112, which can act as a bridge between optical components on optical chip 108 and an external fiber-connector, such as an MT connector. Note that this optical connector integration can be lead-free solder reflow compatible, which means it will maintain good alignment and low-coupling loss between optical chip 110 and waveguide 112 during a subsequent lead-free solder reflow process.

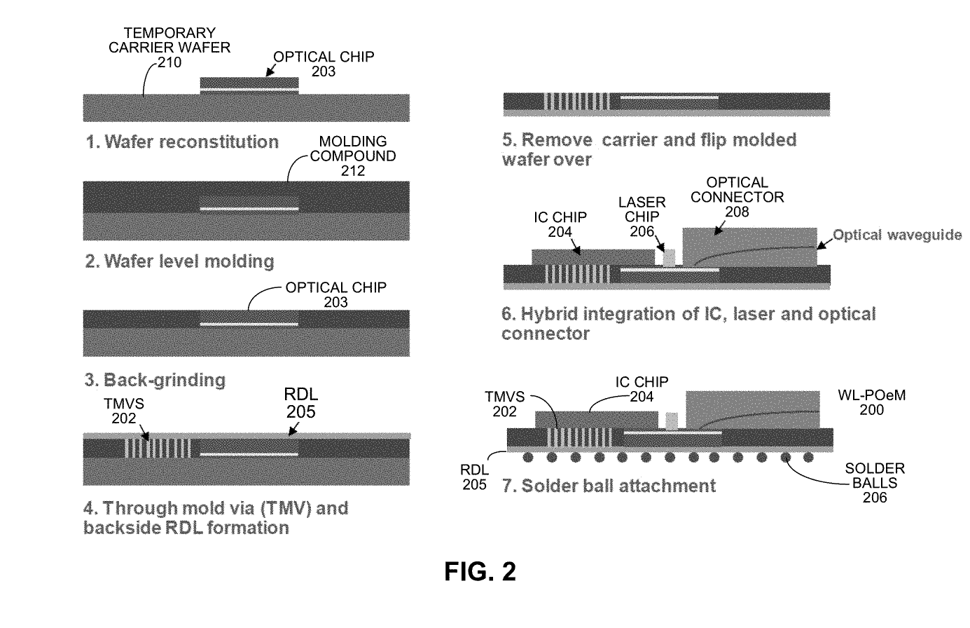

FIG. 2 illustrates an assembly process for constructing an exemplary WL-POeM 200. A number of optical chips, including illustrated optical chip 203, are first bonded face-down at pre-set locations on a temporary carrier wafer 210 through die-to-wafer bonding using a temporary adhesive. Following this, a molding compound 212 is dispensed to encapsulate all of the dies, and is then compressed and cured to create an artificial wafer. This process is called “wafer re-constitution.” Next, a back-grinding operation is performed to reveal the backside of optical chip 203. Then, through-mold vias (TMVs) 202 are formed in the artificial wafer, and one or more back-side redistribution layers (RDL) 205 are formed on the artificial wafer. Next, the temporary carrier wafer 210 is removed. The molded reconstituted wafer is then flipped over and is ready for the chip-attachment operations to attach IC chip 204, laser chip 206 and optical connector 208. Note that these chip-attachment operations, including the attachment sequence and the attachment approach, may vary depending on the types of integrated chips being integrated. Finally, solder balls 206 are attached to RDL 205, and the WL-POeMs are singulated through molded-wafer dicing.

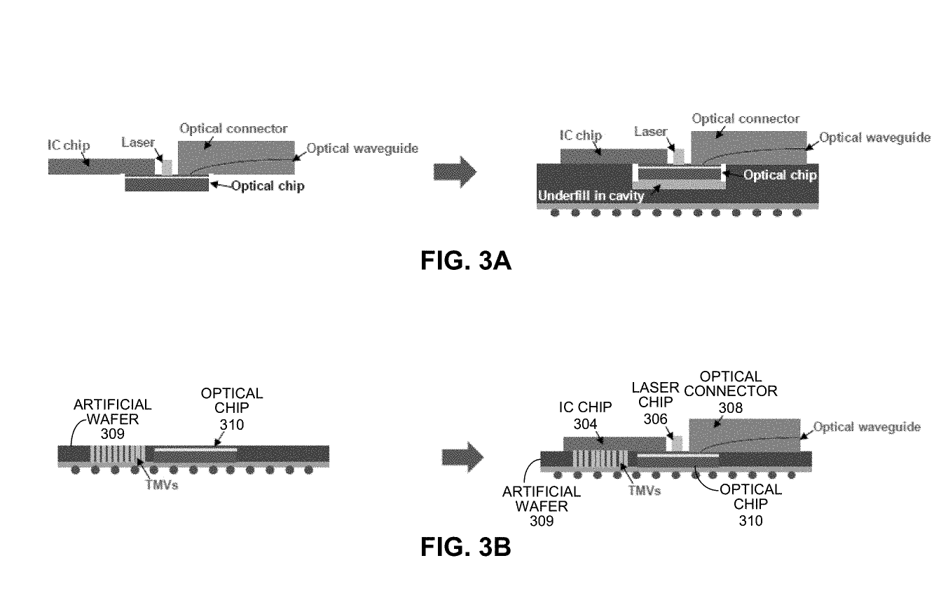

FIG. 3A illustrates the complex bonding process associated with POeM formation, which involves assembling a multi-chip component (including diving boards) onto a substrate with a cavity. In contrast to the complex process illustrated in FIG. 3A, a WL-POeM module can be manufacturing with a standard wafer-level packaging process as is illustrated in FIG. 3B. During this WL-POeM formation process, the hybrid integration of the IC chip 304, the laser chip 306 and the optical connector 308 is performed on a planar-molded artificial wafer 309 with an embedded optical chip 310.

Compared with the previously proposed POeM illustrated in FIG. 1A, the WL-POeM illustrated in FIG. 1B provides a number of improvements, including: (1) a compact footprint; (2) a lower profile; (3) a cavity-free and diving-board-free package; and (4) a wafer-level assembly process. The benefits of these improvements are described in more detail below.

The compact footprint provides a number of advantages. Because there is no cavity in the substrate, many manufacturing-driven “keep-out zones” in the substrate are eliminated or reduced, which significantly reduces the package footprint. For example, by eliminating or reducing the required clearances between: (1) the cavity and the optical chip; (2) the cavity and the substrate edge; and (3) the IC chip and the substrate edge, the substrate footprint can be reduced at least 20%. The compact footprint also results in: less substrate warpage during assembly; enhanced reliability; and increased bandwidth density in the resulting WL-POeM.

The lower profile provides additional advantages. In particular, the lower profile leads to lower electrical parasitic capacitances and less thermal mass, which leads to better thermal performance In a conventional POeM, the minimum substrate thickness is defined by manufacturing design rules associated with building a cavity, such as the clearance between the optical chip and the cavity bottom, and the cavity bottom thickness. In contrast, the molded substrate of the WL-POeM can be made as thin as the embedded optical chip through the back-grinding operation. Hence, by using a molded substrate to fabricate the WL-POeM, the substrate thickness can be reduced by about 70%. The low profile substrate also reduces via length, which enhances power and high-speed signal delivery. Note that for any product-driven volumetric dimension limits, a lower WL-POeM profile provides more room for heat sinks or other cooling components, which facilitates better cooling for high-power-density components such as laser chips.

The cavity-free and diving-board-free package also provides advantages. Note that this cavity-free and diving-board-free package is more manufacturing-compatible and therefore increases assembly yield. Also note that WL-POeM assembly can be performed using an industry-standard wafer-level packaging process, which does not involve substrate cavities and diving board structures. Also, the hybrid integration of the IC chips, laser chips and optical connectors can be performed on a planar-molded artificial wafer with embedded optical chips, which makes it possible to use an efficient automated pick-and-place assembly system.

Finally, the use of a wafer-level packaging process while assembling the WL-POeM can greatly enhance assembly throughput and lower assembly costs. In particular, the hybrid bonding of the IC chip and the laser chip to the molded substrate of the WL-POeM can be performed by using a die-to-wafer bonding process or mass reflow process, either of which provides high throughput and low assembly costs. During the process of assembling a conventional POeM, the IC chip and laser chip can be also integrated through die-to-wafer bonding. However, special chip-singularity steps may be needed to dice the diving board components, which may increase assembly costs and lower the yield. (See U.S. Pat. No. 9,159,861, entitled “Method for Singulating Hybrid Integrated Photonic Chips,” by inventors Chaoqi Zhang, et al., issued 13 Oct. 2015, which is incorporated by reference herein)

### Variations

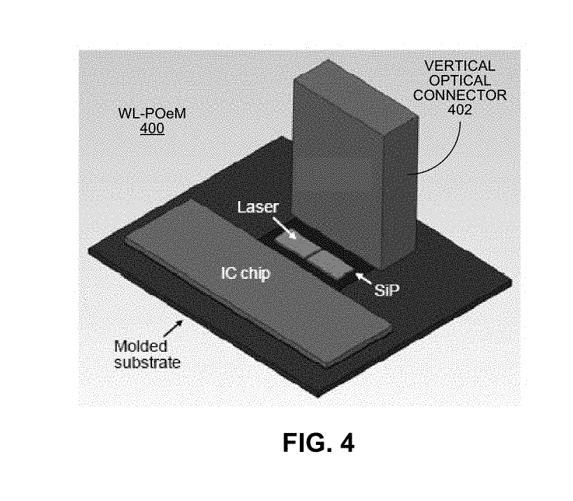

FIG. 4 illustrates a WL-POeM 400 that includes a vertical optical connector 402. Note that the low-profile of optical connector 108 of the WL-POeM 120 shown in FIG. 1B minimizes the height of WL-POeM 120, but also has a large footprint, and consequently occupies a significant amount of area on molded substrate 103. In contrast, the vertical optical connector 402 illustrated in FIG. 4 has a smaller footprint, and can also satisfy other mechanical design requirements.

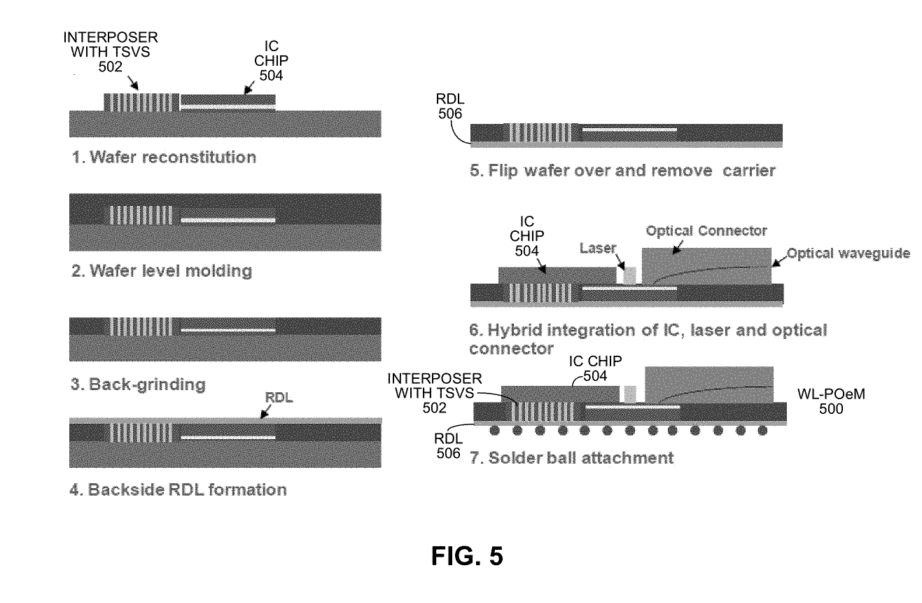

FIG. 5 illustrates a process for fabricating a WL-POeM 500 with an embedded silicon interposer 502 that contains through-silicon vias (TSVs). Note that the WL-POeM 200 created by the manufacturing process illustrated in FIG. 2 uses through-mold vias (TMVs) 202 to route signals from IC chip 204 to the solder balls 206. However, the routing capability of such TMVs 202 can make it challenging to fan out the fine-pitch I/O signal lines on IC chip 204 for high-bandwidth applications. To address this fan-out limitation, the WL-POeM 500 illustrated in FIG. 5 includes an embedded interposer with TSVs 502, which does not suffer from the same fan-out limitations. During the wafer reconstitution process illustrated in FIG. 5, a silicon (or glass) interposer with TSVs 502 is embedded along with IC chip 504. Note that this interposer with TSVs 502 can be used in combination with on-chip RDL 506 to facilitate high-bandwidth routing for electrical signals from IC chip 504.

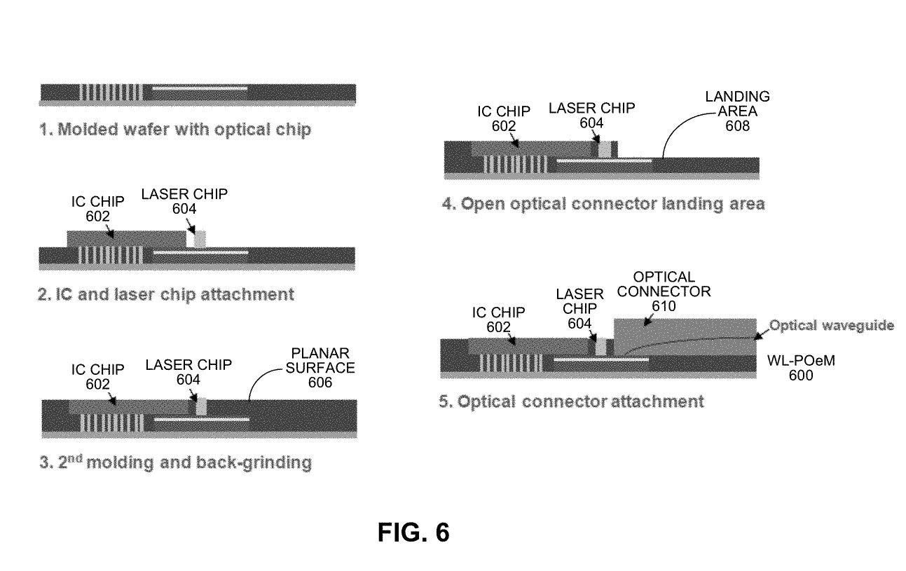

FIG. 6 illustrates a process for fabricating a WL-POeM 600 that includes an additional second molding process. As shown in FIG. 6, a second molding process (called an “over-molding process”) and an additional back-grinding process are performed in step 3, after IC chip 602 and laser chip 604 are integrated in step 2. The resulting over-molding layer enhances reliability and protects IC chip 602 and laser chip 604. Moreover, the revealed planar back surface 606 of IC chip 602 and laser chip 604 provides a flat surface to attach cooling components such as heat sinks and heat pipes. Note that additional molding processes can be repeated to create a three-dimensional stack of components. After all of the molding and grinding processes are complete, a clean landing area 608 for an optical connector 610 can be reopened. Note that with precise positional and dimensional control, the landing opening associated with landing area 608 can provide an alignment feature, which can be used during the process of attaching optical connector 610.

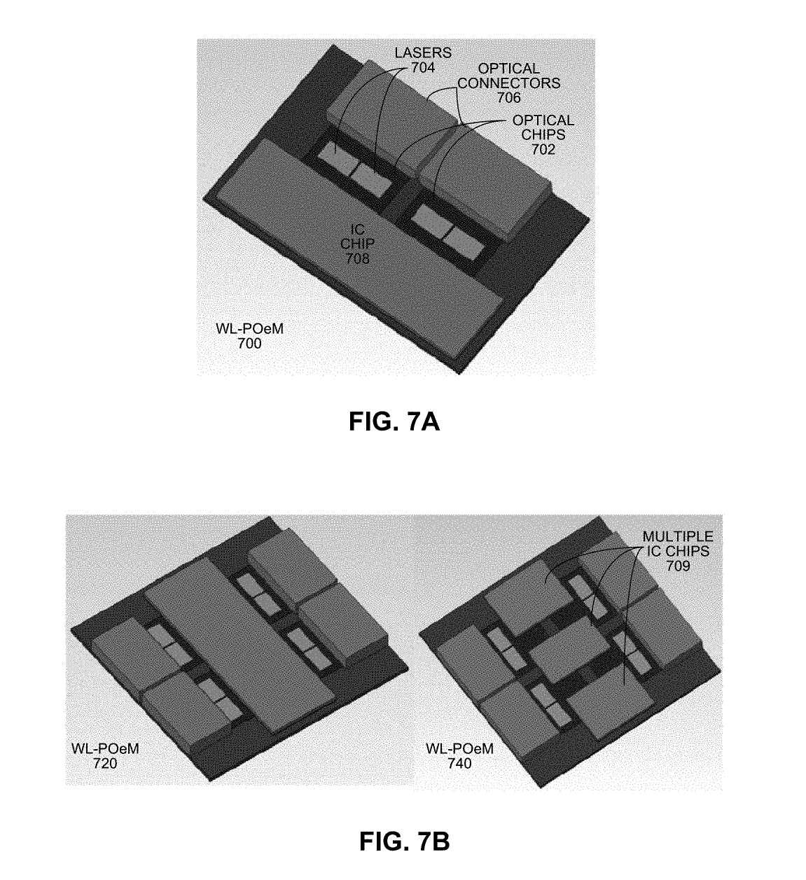

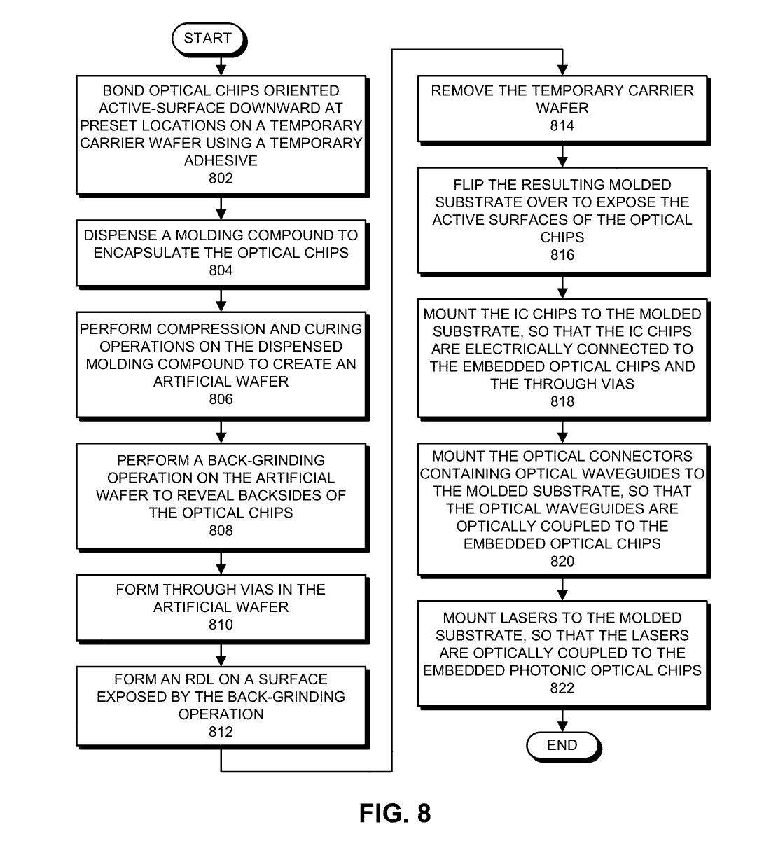

The wafer-level packaging process described above also enhances the scalability of the resulting WL-POeM. As shown in FIGS. 7A-7B, by using the WL-POeM manufacturing process flow, the resulting WL-POeMs 700, 720 and 740 can include multiple optical chips. Also, thanks to the compact footprint of the WL-POeM, the size of a WL-POeM module 700 with a given number of optical chips 702 (as well as lasers 704, optical connectors 706 and IC chips 708-709) can be smaller than a corresponding POeM with the same number of optical chips. This size reduction can mitigate manufacturing difficulties and reliability issues for large-scale systems. In addition, as shown in WL-POeM 740 illustrated in FIG. 7B, multiple IC chips 709 can be integrated into a large-scale WL-POeM instead of a single large IC chip 708, which can reduce the module cost and increase assembly flexibility.

### Assembly Process

The process of assembling an exemplary WL-POeM proceeds as follows. First, optical chips are bonded so that they are oriented active-surface downward at preset locations on a temporary carrier wafer using a temporary adhesive (step 802). Next, a molding compound is dispensed to encapsulate the optical chips (step 804), and then compression and curing operations are performed on the dispensed molding compound to create an artificial wafer (step 806). Then, a back-grinding operation is performed on the artificial wafer to reveal backsides of the optical chips (step 808). Next, through vias are formed in the artificial wafer (step 810). After this step, a redistribution layer (RDL) is formed on a surface exposed by the back-grinding operation (step 812), wherein the RDL facilitates routing signals from the vias to solder balls. Then, the temporary carrier wafer is removed (step 814), and the resulting molded substrate is flipped over to expose the active surfaces of the optical chips (step 816). Next, integrated circuit (IC) chips are mounted to the molded substrate, so that the IC chips are electrically connected to the embedded optical chips and the through vias (step 818). Then, optical connectors containing optical waveguides are mounted to the molded substrate, so that the optical waveguides are optically coupled to the embedded optical chips (step 820). Finally, lasers are mounted to the molded substrate, so that the lasers are optically coupled to the embedded photonic optical chips (step 822).

### System

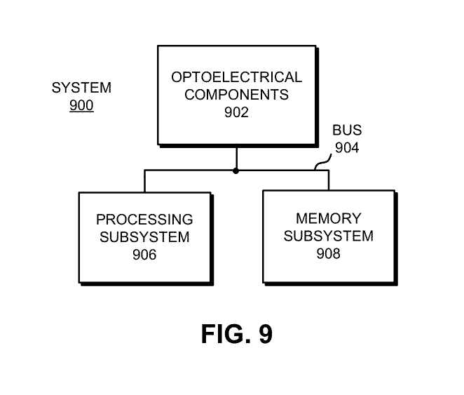

One or more of the preceding embodiments of the WL-POeM 120 illustrated in FIG. 1B may be included in a system or device. More specifically, FIG. 9 illustrates a system 900 that includes optoelectrical components 902. System 900 also includes a processing subsystem 906 (with one or more processors) and a memory subsystem 908 (with memory).

In general, system 900 may be implemented using a combination of hardware and/or software. Thus, system 900 may include one or more program modules or sets of instructions stored in a memory subsystem 908 (such as DRAM or another type of volatile or non-volatile computer-readable memory), which, during operation, may be executed by processing subsystem 906. Furthermore, instructions in the various modules in memory subsystem 908 may be implemented in: a high-level procedural language, an object-oriented programming language, and/or in an assembly or machine language. Note that the programming language may be compiled or interpreted, e.g., configurable or configured, to be executed by the processing subsystem.

Components in system 900 may be coupled by signal lines, links or buses, for example bus 904. These connections may include electrical, optical, or electro-optical communication of signals and/or data. Furthermore, in the preceding embodiments, some components are shown directly connected to one another, while others are shown connected via intermediate components. In each instance, the method of interconnection, or “coupling,” establishes some desired communication between two or more circuit nodes, or terminals. Such coupling may often be accomplished using a number of photonic or circuit configurations, as will be understood by those of skill in the art; for example, photonic coupling, AC coupling and/or DC coupling may be used.

In some embodiments, functionality in these circuits, components and devices may be implemented in one or more: application-specific integrated circuits (ASICs), field-programmable gate arrays (FPGAs), and/or one or more digital signal processors (DSPs). Furthermore, functionality in the preceding embodiments may be implemented more in hardware and less in software, or less in hardware and more in software, as is known in the art. In general, system 900 may be at one location or may be distributed over multiple, geographically dispersed locations.

System 900 may include: a switch, a hub, a bridge, a router, a communication system (such as a wavelength-division-multiplexing communication system), a storage area network, a data center, a network (such as a local area network), and/or a computer system (such as a multiple-core processor computer system). Furthermore, the computer system may include, but is not limited to: a server (such as a multi-socket, multi-rack server), a laptop computer, a communication device or system, a personal computer, a work station, a mainframe computer, a blade, an enterprise computer, a data center, a tablet computer, a supercomputer, a network-attached-storage (NAS) system, a storage-area-network (SAN) system, a media player (such as an MP3 player), an appliance, a subnotebook/netbook, a tablet computer, a smartphone, a cellular telephone, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, and/or

another electronic device.

Moreover, the optoelectrical components 902 can be used in a wide variety of applications, such as: communications (for example, in a transceiver, an optical interconnect or an optical link, such as for intra-chip or inter-chip communication), a radio-frequency filter, a bio-sensor, data storage (such as an optical-storage device or system), medicine (such as a diagnostic technique or surgery), a barcode scanner, metrology (such as precision measurements of distance), manufacturing (cutting or welding), a lithographic process, data storage (such as an optical-storage device or system) and/or entertainment (a laser light show).

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

1. An optoelectronic module, comprising:
one or more optical chips;
a molded substrate, which is molded around the one or more optical chips, so that the one or more optical chips are embedded in the molded substrate, and an active surface of each optical chip remains exposed;
wherein the molded substrate includes one or more through vias that provide electrical signal paths through the molded substrate;
one or more integrated circuit (IC) chips flip-mounted to the molded substrate and electrically connected to the one or more embedded optical chips and the one or more through vias;
one or more optical connectors containing optical waveguides flip-mounted on the molded substrate and optically coupled to the one or more embedded optical chips; and
wherein the optoelectronic module does not comprise a structural substrate on which the one or more optical chips and the one or more IC chips are mounted.

2. The optoelectronic module of claim 1, further comprising one or more lasers mounted to the molded substrate and optically coupled to the one or more embedded optical chips.

3. The optoelectronic module of claim 1, wherein the one or more through vias comprise through-mold vias (TMVs), which are formed in the molded substrate.

4. The optoelectronic module of claim 1, wherein the one or more through vias comprise through-silicon vias (TSVs) located in one or more interposer chips, which are embedded in the molded substrate.

5. The optoelectronic module of claim 1, wherein a face of the molded substrate, which is opposite from the exposed active surfaces of the embedded optical chips, includes a redistribution layer that facilitates routing signals from the one or more through vias to one or more electrical connectors.

6. The optoelectronic module of claim 1, wherein the one or more optical connectors include at least one vertical optical connector.

7. (canceled)

8. The optoelectronic module of claim 1, wherein the one or more IC chips and the one or more optical connectors are mounted to the molded substrate using an automated pick-and-place assembly process with wafer-level bonding.

9. A system, comprising:
at least one processor;
at least one memory coupled to the at least one processor; and
an optoelectronic module that is part of an optical communication system that communicates optical signals throughout the system, wherein the optoelectronic module comprises:
one or more optical chips;
a molded substrate, which is molded around the one or more optical chips, so that the one or more optical chips are embedded in the molded substrate, and an active surface of each optical chip remains exposed;
wherein the molded substrate includes one or more through vias that provide electrical signal paths through the molded substrate;
one or more integrated circuit (IC) chips flip-mounted to the molded substrate and electrically connected to the one or more embedded optical chips and the one or more through vias;
one or more optical connectors containing optical waveguides flip-mounted on the molded substrate and optically coupled to the one or more embedded optical chips; and
wherein the optoelectronic module does not comprise a structural substrate on which the one or more optical chips and the one or more IC chips are mounted.

10. The system of claim 9, further comprising one or more lasers mounted to the molded substrate and optically coupled to the one or more embedded optical chips.

11. The system of claim 9, wherein the one or more through vias comprise through-mold vias (TMVs), which are formed in the molded substrate.

12. The system of claim 9, wherein the one or more through vias comprise through-silicon vias (TSVs) located in one or more interposer chips, which are embedded in the molded substrate.

13. The system of claim 9, wherein a face of the molded substrate, which is opposite from the exposed active surfaces of the embedded optical chips, includes a redistribution layer that facilitates routing signals from the one or more through vias to one or more electrical connectors.

14. The system of claim 9, wherein the one or more optical connectors include at least one vertical optical connector.

15. (canceled)

16. The system of claim 9, wherein the one or more IC chips and the one or more optical connectors are mounted to the molded substrate using an automated pick-and-place assembly process with wafer-level bonding.

17. A method for manufacturing an optoelectronic module, comprising:
fabricating a molded substrate, which is molded around one or more optical chips, so that the one or more optical chips are embedded in the molded substrate, and an active surface of each optical chip remains exposed, and wherein the molded substrate includes one or more through vias that provide electrical signal paths through the molded substrate;
mounting the one or more integrated circuit (IC) chips to the molded substrate, so that the one or more IC chips are electrically connected to the one or more embedded optical chips and the one or more through vias;
mounting the one or more optical connectors containing optical waveguides to the molded substrate, so that the one or more optical connectors are optically coupled to the one or more embedded optical chips; and
wherein the optoelectronic module does not comprise a structural substrate on which the one or more optical chips and the one or more IC chips are mounted.

18. The method of claim 17, wherein fabricating the molded substrate comprises:
bonding the one or more optical chips oriented active-surface downward at preset locations on a temporary carrier wafer using a temporary adhesive;
dispensing a molding compound to encapsulate the one or more optical chips;
performing compression and curing operations on the dispensed molding compound to create an artificial wafer;
performing a back-grinding operation on the artificial wafer to reveal backsides of the one or more optical chips;
forming the one or more through vias in the artificial wafer;
forming a redistribution layer (RDL) on a surface exposed by the back-grinding operation, wherein the RDL facilitates routing signals from the one or more through vias to one or more electrical connectors;
removing the temporary carrier wafer; and
flipping the resulting molded substrate over to expose the active surfaces of the one or more optical chips to facilitate the subsequent mounting of the one or more IC chips and the one or more optical connectors.

19. The method of claim 17, further comprising mounting one or more lasers to the molded substrate, so that the one or more lasers are optically coupled to the one or more embedded optical chips.

20. The method of claim 17, wherein mounting the one or more IC chips and the one or more optical connectors to the molded substrate involves using an automated pick-and-place assembly process with wafer-level bonding.

21. The optoelectronic module of claim 1, further comprising an over-molding layer molded over the one or more IC chips and the molded substrate.

22. The system of claim 9, further comprising an over-molding layer molded over the one or more IC chips and the molded substrate.
